(19) United States
(12) Patent Application Publication
(10) Pub. No.: US 2025/0050427 A1
(43) Pub. Date: Feb. 13, 2025

(54) COATED CUTTING TOOL

(71) Applicant: AB SANDVIK COROMANT, Sandviken (SE)

(72) Inventors: Katherine CALAMBA, Sandviken (SE); Lars JOHNSON, Sandviken (SE); Ebba SAIKOFF, Sandviken (SE)

(21) Appl. No.: 18/722,027

(22) PCT Filed: Dec. 21, 2022
(86) PCT No.: PCT/EP2022/087307

§ 371 Date: Jun. 20, 2024

(30) Foreign Application Priority Data
Dec. 22, 2021 (EP) 21216990.8

(51) Int. Cl. B23B 27/14

(52) U.S. Cl. CPC B23B 27/148; B23B 2224/00; B23B 2224/24; B23B 2228/08; B23B 2228/105; B23B 2228/36

(57) ABSTRACT

The present invention relates to a coated cutting tool including a substrate and a coating. The coating has, from about 0.5 to about 10 μm, a nano-multilayer of alternating nanolayers of a first nanolayer type of Ti₁₋ₓAlₓN, wherein 0.45≤x<0.67, a second nanolayer type of Cr_{1-y}Al_{y}N, wherein 0.60≤y≤0.80, and a third nanolayer type of Ti_{1-z}Si_{z}N, wherein 0.14≤z≤0.25. An average nanolayer thickness of each of the nanolayer types Ti₁₋ₓAlₓN, Cr_{1-y}Al_{y}N and Ti_{1-z}Si_{z}N in the nano-multilayer is ≥1 nm but <3 nm.

### TECHNICAL FIELD

The present invention relates to a coated cutting tool comprising a coating comprising a nano-multilayer of alternating nanolayers of Ti₁₋ₓAlₓN, 0.45≤x<0.67, Cr_{1-y}Al_{y}N, 0.60≤y≤0.80, and Ti_{1-z}Si_{z}N, 0.14≤z≤0.25.

### BACKGROUND

Metal machining operations include, for example, turning, milling, and drilling. In order to provide a long tool life, a coated cutting tool, such as an insert, should have high resistance against different types of wear. In order to increase wear resistance of a cutting tool various types of wear resistant coatings are known in the art.

A cutting tool generally has at least one rake face and at least one flank face. A cutting edge is present where a rake face and flank face meet.

Flank wear obviously takes place on a flank face of the cutting edge, mainly from an abrasive wear mechanism. The flank face is subjected to workpiece movement and too much flank wear will lead to poor surface texture of the workpiece, inaccuracy in the cutting process and increased friction in the cutting process.

If a better flank wear resistance is provided longer tool life is provided for certain metal machining operations.

Different metal machining operations affect a coated cutting tool in different ways. Turning, for example, is a continuous metal machining operation while milling is more intermittent in nature. In milling the thermal and mechanical load will vary over time. Thermal load induces thermal tensions which may lead to so-called thermal cracks, herein referred to as “comb cracks”, in the coatings, while the later may cause fatigue in the cutting edge leading to chipping, i.e., small fragments of the cutting edge loosening from the rest of the substrate. Thus, common wear types of a coated cutting tool in milling are cracking and chipping. A high comb crack resistance is thus of great importance for tool lifetime in such cutting operations.

A high level of toughness of the coating, in particular at the cutting edge, may also reduce chipping. A high edge line toughness, thus, also increases tool lifetime.

There is a continuing demand for coated cutting tools in which the coating has excellent properties in terms of wear resistance, comb crack resistance etc. in order to provide a cutting tool with superior properties than currently available cutting tools on the market. If one or more of the above-mentioned properties are improved then longer tool life is provided.

Nano-multilayered coatings are being used in the area of cutting tools for metal machining. In these coatings at least two layers which are different in some respect alternate forming a coating of a stack of nanolayers.

### OBJECT OF THE INVENTION

There is an object of the present invention to provide a coated cutting tool which, at least, shows high flank wear resistance and preferably also high comb crack resistance, most preferably also high edge line toughness.

### SUMMARY OF THE INVENTION

The object of the invention is provided by a coated cutting tool comprising a substrate and a coating, wherein the coating comprises a from about 0.5 to about 10 μm nano-multilayer of alternating nanolayers of a first nanolayer type being Ti₁₋ₓAlₓN, 0.45≤x<0.67, a second nanolayer type (10) being Cr_{1-y}Al_{y}N, 0.60≤y≤0.80, and a third nanolayer type (11) being Ti_{1-z}Si_{z}N, 0.14≤z≤0.25, the average nanolayer thickness of each of the nanolayer types Ti₁₋ₓAlₓN (9), Cr_{1-y}Al_{y}N (10) and Ti_{1-z}Si_{z}N (11) in the nano-multilayer (8) is ≥1 nm but <3 nm.

By “nano-multilayer of alternating nanolayers of a first nanolayer type, a second nanolayer type, and a third nanolayer type” is herein meant that the different types of nanolayers are generally alternating in a certain order in the nano-multilayer. However, due to the way chosen for depositing the nano-multilayer in a PVD reactor, for example using a so called three-fold rotation of the tools being coated, there may be an altering of the order of the three types of nanolayers at some places within the nano-multilayer.

In one embodiment there is a ratio in the nano-multilayer between the sum of nanolayer thicknesses of all of each nanolayer types, Ti₁₋ₓAlₓN:Cr_{1-y}Al_{y}N:Ti_{1-z}Si_{z}N, being a:b:c, wherein 0.5<a<3, 0.5<b<3, 0.5<c<3, preferably 0.75<a<2.5, 0.75<b<2.5, 0.75<c<2.5, most preferably 0.9<a<2.25, 0.9<b<2.25, 0.9<c<2.25.

The ratio between the sum of nanolayer thicknesses of each nanolayer type, Ti₁₋ₓAlₓN:Cr_{1-y}Al_{y}N:Ti_{1-z}Si_{z}N, in the nano-multilayer, i.e., a:b:c, can be determined by Scanning Transmission Electron Microscopy (STEM) analysis, preferably in combination with Energy-dispersive X-ray spectroscopy (EDS), where over a distance along a normal to the substrate surface the elemental composition and thicknesses of individual nanolayers are determined. A distance of at least 25 times the average nanolayer thickness is used. The sum of nanolayer thicknesses for nanolayers of the first nanolayer type Ti₁₋ₓAlₓN is “a”, the sum of nanolayer thicknesses for nanolayers of the second nanolayer type Cr_{1-y}Al_{y}N is “b”, and the sum of nanolayer thicknesses for nanolayers of the third nanolayer type Ti_{1-z}Si_{z}N is “c”.

The average nanolayer thickness of each of the nanolayer types Ti₁₋ₓAlₓN, Cr_{1-y}Al_{y}N, and Ti_{1-z}Si_{z}N in the nano-multilayer can also be determined by the above described STEM/EDS analysis.

For the first nanolayer type being Ti₁₋ₓAlₓN, suitably 0.50≤x≤0.62, preferably 0.55≤x≤0.62.

For the second nanolayer type being Cr_{1-y}Al_{y}N, suitably 0.65≤y≤0.75.

For the third nanolayer type being Ti_{1-z}Si_{z}N, suitably 0.15≤z≤0.23, preferably 0.16≤z≤0.21.

The average nanolayer thickness in the nano-multilayer of each of the nanolayer types Ti₁₋ₓAlₓN, Cr_{1-y}Al_{y}N, and Ti_{1-z}Si_{z}N in the nano-multilayer is suitably from 1 to 2.8 nm, preferably from 1 to 2.5 nm, more preferably from 1.5 to 2.5 nm, most preferably from 1.8 to 2.2 nm.

The ratio of average nanolayer thickness in the nano-multilayer between any one of the nanolayer types Ti₁₋ₓAlₓN, Cr_{1-y}Al_{y}N, and Ti_{1-z}Si_{z}N to any of the remaining two of the nanolayer types Ti₁₋ₓAlₓN, Cr_{1-y}Al_{y}N, and Ti_{1-z}Si_{z}N in the nano-multilayer is suitably of from 0.1 to 10, preferably from 0.5 to 5, most preferably from 0.8 to 2.

Suitably, within a sequence of 10 consecutive nanolayers, preferably 8, most preferably 6, consecutive nanolayers, in the nano-multilayer there are all of the nanolayer types Ti₁₋ₓAlₓN, Cr_{1-y}Al_{y}N, and Ti_{1-z}Si_{z}N present.

The thickness of the nano-multilayer is suitably from about 1 to about 8 μm, preferably from about 1.5 to about 5 μm.

In one embodiment, the coating comprises an inner layer of a nitride of one or more of Ti and Cr, or one or more of Ti and Cr in combination with Al, below the nano-multilayer, preferably closest to the substrate. More specifically, in one embodiment, the inner layer is TiN, CrN, (Ti, Cr)N, (Cr,Al)N or (Ti,Al)N. In one embodiment the inner layer is (Cr,Al)N or (Ti,Al)N. In another embodiment the inner layer is TiN or (Ti,Al)N. The (Ti,Al)N layer may either be a monolayer or a nano-multilayer of alternating nanolayers of different Ti/Al ratio. The (Cr,Al)N layer may either be a monolayer or a nano-multilayer of alternating nanolayers of different Cr/Al ratio.

Preferably, the inner layer is (Ti, Al)N. If (Ti,Al)N is used as the inner layer then the (Ti, Al)N is suitably Ti₁₋ₜAlₜN, 0.45≤t≤0.67, preferably 0.50≤t≤0.62, most preferably 0.55≤t≤0.62. In a preferred embodiment the Ti—Al relation in the (Ti, Al)N of the inner layer is the same as the Ti-AI relation in the first nanolayer type of the nano-multilayer. This is because this simplifies the production when a same target can be used as already being used for the nano-multilayer.

The thickness of the inner layer is suitably from about 0.1 to about 3 μm, preferably from about 0.2 to about 2 μm, most preferably from about 0.5 to about 2 μm.

In one embodiment, for the purpose of having control of the colour of the coated cutting tool, the coating comprises an outermost single layer of any one of the first nanolayer type Ti₁₋ₓAlₓN, with 0.45≤x<0.67 or 0.50≤x≤0.62 or 0.55≤x≤0.62, the second nanolayer type Cr_{1-y}Al_{y}N with 0.60≤y≤0.80 or 0.65≤y≤0.75, or the third nanolayer type Ti_{1-z}Si_{z}N, with 0.14≤z≤0.25 or 0.15≤z≤0.23 or 0.16≤z≤0.21.

The values of x, y or z in the outermost layer is preferably the same as x, y or z in the Ti₁₋ₓAlₓN, Cr_{1-y}Al_{y}N, or Ti_{1-z}Si_{z}N in the nano-multilayer. This is because this simplifies the production when a same target can be used as already being used for the nano-multilayer.

The thickness of this outermost layer is suitably from about 0.1 to about 0.5 μm, preferably from about 0.1 to about 0.3 μm.

The nanolayers of the first nanolayer type, the second nanolayer type and the third nanolayer type are suitably cathodic arc evaporation deposited layers. Also the optional inner layer of TiN or (Ti,Al)N, as well as the optional outermost single layer are suitably cathodic arc evaporation deposited layers.

The substrate of the coated cutting tool can be selected from the group of cemented carbide, cermet, ceramic, cubic boron nitride and high speed steel. In one embodiment the substrate is a cemented carbide comprising from 5 to 18 wt % Co

The coated cutting tool is suitably a cutting tool insert, a drill, or a solid end-mill, for metal machining. The cutting tool insert is, for example, a turning insert or a milling insert.

### BRIEF DESCRIPTIONS OF THE DRAWINGS

FIG. 1 shows a schematic view of one embodiment of a cutting tool being a milling insert.

FIG. 2 shows a schematic view of one embodiment of a cutting tool being a turning insert.

FIG. 3 shows a schematic view of a cross section of an embodiment of the coated cutting tool of the present invention showing a substrate and a multilayer coating.

FIG. 4 shows a schematic view of a cross section of an embodiment of the coated cutting tool of the present invention showing a substrate and a coating comprising different layers.

### DETAILED DESCRIPTION OF EMBODIMENTS IN DRAWINGS

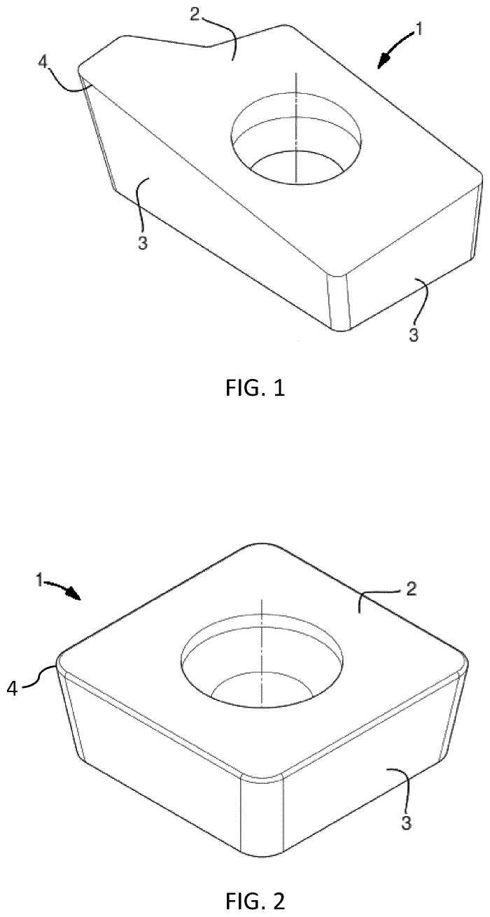

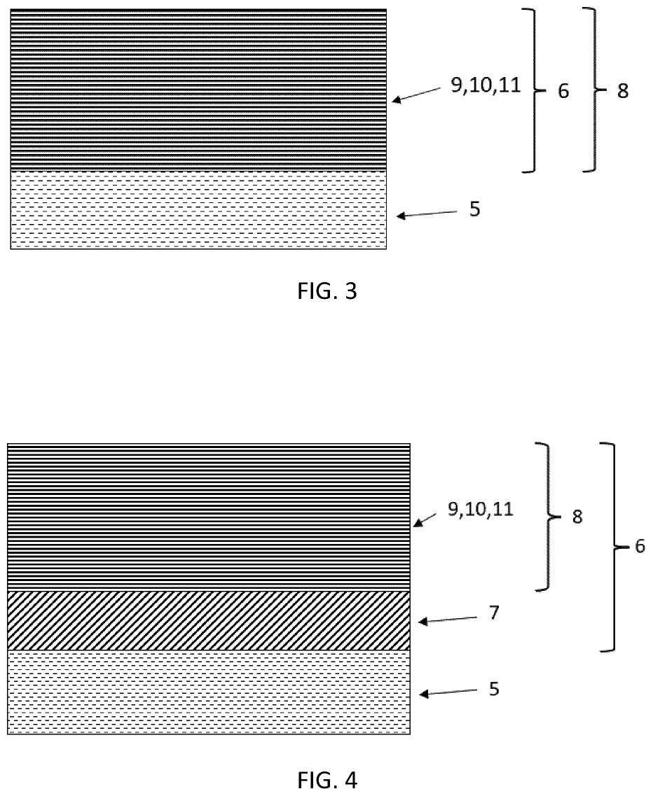

FIG. 1 shows a schematic view of one embodiment of a cutting tool 1 having a rake face 2 and flank faces 3 and a cutting edge 4. The cutting tool 1 is in this embodiment a milling insert. FIG. 2 shows a schematic view of one embodiment of a cutting tool 1 having a rake face 2 and flank face 3 and a cutting edge 4. The cutting tool 1 is in this embodiment a turning insert. FIG. 3 shows a schematic view of a cross section of an embodiment of the coated cutting tool of the present invention having a substrate 5 and a coating 6. The coating 6 consisting of a nano-multilayer 8 of alternating nanolayers 9, 10 and 11 being Ti₁₋ₓAlₓN 9, Cr_{1-y}Al_{y}N 10 and Ti_{1-z}Si_{z}N 11. FIG. 4 shows a schematic view of a cross section of an embodiment of the coated cutting tool of the present invention having a substrate 5 and a coating 6. The coating 6 consisting of a first (Ti,Al)N innermost layer 7 followed by a nano-multilayer 8 of alternating nanolayers 9, 10 and 11 being Ti₁₋ₓAlₓN 9, Cr_{1-y}Al_{y}N 10 and Ti_{1-z}Si_{z}N 11.

### DETAILED DESCRIPTION OF EMBODIMENTS

In one embodiment, there is a ratio in the nano-multilayer 8 between the sum of nanolayer thicknesses of each nanolayer type 9, 10, 11, Ti₁₋ₓAlₓN:Cr_{1-y}Al_{y}N:Ti_{1-z}Si_{z}N, in the nano-multilayer 8, a:b:c, 0.75<a<1.25, 0.75<b<1.25, 1.5<c<2.5, preferably 0.9<a<1.1, 0.9<b<1.1, 1.75<c<2.25. In this embodiment the nano-multilayer 8 suitably comprises a repeating sequence of consecutive nanolayers of the first nanolayer type 9, Ti₁₋ₓAlₓN, the second nanolayer type 10, Cr_{1-y}Al_{y}N, and the third nanolayer type 11, Ti_{1-z}Si_{z}N, in the order Ti₁₋ₓAlₓN/Ti_{1-z}Si_{z}N/Cr_{1-y}Al_{y}N/Ti_{1-z}Si_{z}N. The nano-multilayer 8 is suitably composed of (Ti₁₋ₓAlₓN/Ti_{1-z}Si_{z}N/Cr_{1-y}Al_{y}N/Ti_{1-z}Si_{z}N . . . )ₘ, m=15-1500, suitably m=30-800.

In a further embodiment, there is a ratio in the nano-multilayer 8 between the sum of nanolayer thicknesses of each nanolayer type 9, 10, 11, Ti₁₋ₓAlₓN:Cr_{1-y}Al_{y}N:Ti_{1-z}Si_{z}N, in the nano-multilayer 8, a:b:c, 1.5<a<2.5, 0.75<b<1.25, 0.75<c<1.25, preferably 1.75<a<2.25, 0.9<b<1.1, 0.9<c<1.1. In this embodiment the nano-multilayer 8 suitably comprises a repeating sequence of consecutive nanolayers of the first nanolayer type 9, Ti₁₋ₓAlₓN, the second nanolayer type 10, Cr_{1-y}Al_{y}N, and the third nanolayer type 11, Ti_{1-z}Si_{z}N, in the order Ti₁₋ₓAlₓN/Cr_{1-y}Al_{y}N/Ti₁₋ₓAlₓN/Ti_{1-z}Si_{z}N. The nano-multilayer (8) is suitably composed of (Ti₁₋ₓAlₓN/Cr_{1-y}Al_{y}N/Ti₁₋ₓAlₓN/Ti_{1-z}Si_{z}N)ₙ, n=15-1500, suitably n=30-800.

In a further embodiment, there is a ratio in the nano-multilayer 8 between the sum of nanolayer thicknesses of each nanolayer type 9, 10, 11, Ti₁₋ₓAlₓN:Cr_{1-y}Al_{y}N:Ti_{1-z}Si_{z}N, in the nano-multilayer 8, a:b:c, 0.75<a<1.25, 1.5<b<2.5, 0.75<c<1.25, preferably 1.75<a<2.25, 0.9<b<1.1, 0.9<c<1.1. In this embodiment the nano-multilayer 8 suitably comprises a repeating sequence of consecutive nanolayers of the first nanolayer type 9, Ti₁₋ₓAlₓN, the second nanolayer type 10, Cr_{1-y}Al_{y}N, and the third nanolayer type 11, Ti_{1-z}Si_{z}N, in the order Ti₁₋ₓAlₓN/Cr_{1-y}Al_{y}N/Ti_{1-z}Si_{z}N/Cr_{1-y}Al_{y}N. The nano-multilayer 8 is suitably composed of (Ti₁₋ₓAlₓN/Cr_{1-y}Al_{y}N/Ti_{1-z}Si_{z}N/Cr_{1-y}Al_{y}N)ₚ, p=15-1500, suitably p=30-800.

In a further embodiment, there is a ratio in the nano-multilayer 8 between the sum of nanolayer thicknesses of each nanolayer type 9, 10, 11, Ti₁₋ₓAlₓN:Cr_{1-y}Al_{y}N:Ti_{1-z}Si_{z}N, in the nano-multilayer 8, a:b:c, 0.75<a<1.25, 0.75<b<1.25, 0.75<c<1.25, preferably 0.9<a<1.1, 0.9<b<1.1, 0.9<c<1.1. In this embodiment the nano-multilayer 8 suitably comprises a repeating sequence of consecutive nanolayers of the first nanolayer type 9, Ti₁₋ₓAlₓN, the second nanolayer type 10, Cr_{1-y}Al_{y}N, and the third nanolayer type 11, Ti_{1-z}Si_{z}N, in the order Ti₁₋ₓAlₓN/Cr_{1-y}Al_{y}N/Ti_{1-z}Si_{z}N. The nano-multilayer 8 is suitably composed of (Ti₁₋ₓAlₓN/Cr_{1-y}Al_{y}N/Ti_{1-z}Si_{z}N)_{q}, q=20-2000, suitably q=40-1000.

### EXAMPLES

It should be noted that there will be a small deviation between the elemental relatation of Ti and Al, the elemental relation of Cr and Al and the elemental relatation of Ti and Si in the targets used in the PVD deposition process and their elemental relation in the respective deposited nitride layer. One reason for this can, for example, be due to different tendencies for re-sputtering for different elements.

The actual elemental composition in the different nano-multilayer types can, for example, be determined by using energy-dispersive X-ray spectroscopy (EDS) in Transmission Electron Microscopy (TEM) on a cross-section of the coating.

Alternatively, the actual elemental composition in the different nano-multilayer types can be found by using energy-dispersive X-ray spectroscopy (EDS) in TEM or in Scanning Electron Microscopy (SEM) of a monolayer deposited at the same conditions as a respective nanolayer.

Within the relevant ranges of the contents of elements in the nanolayers of the present invention the following estimations can be made:

For a (Ti, Al)N layer the actual percentage of Al out of Ti+Al will be about 1-2 at. % units below the Al content in the (Ti,Al) target.

For a (Cr, Al)N layer the actual percentage of Al out of Cr+Al will be about 2-3 at. % units below the Al content in the (Cr,Al) target.

For a (Ti, Si)N layer the actual percentage of Si out of Ti+Si will be about 2-3 at. % units below the Si content in the (Ti, Si) target.

Thus, there are only small deviations from the theoretical composition seen. In the following examples the Ti, Al, Cr and Si contents in the deposited nitride layers are written as present in the respective target compositions used in the PVD deposition process.

The nanolayer thicknesses can be measured by using transmission electron microscopy (TEM) analysis.

### Example 1

Coated cutting tools were provided comprising a nano-multilayer of Ti_{0.40}Al_{0.60}N, Cr_{0.30}Al_{0.70}N and Ti_{0.80}Si_{0.20}N (based on target compositions) nanolayers deposited on sintered cemented carbide cutting tool insert blanks of the geometries CNMG120408MM and R390-11T308M-PM. The composition of the cemented carbide was 10 wt % Co, 0.4 wt % Cr and rest WC. The cemented carbide blanks were coated by cathodic arc evaporation in a vacuum chamber comprising four arc flanges, each flange comprising several cathode evaporators. Targets of Ti_{0.80}Si_{0.20} were mounted in the evaporators in two of the flanges opposite each other. The remaining targets Cr_{0.30}Al_{0.70} and Ti_{0.40}Al_{0.60} were mounted in the evaporators in the two remaining flanges opposite each other. The targets were circular and planar with a diameter of 100 mm available on the open market. Suitable target technology packages for arc evaporation are available from suppliers on the market such as IHI Hauzer Techno Coating B.V., Kobelco (Kobe Steel Ltd.) and Oerlikon Balzers.

The uncoated blanks were mounted on pins that undergo a three-fold rotation in the PVD chamber.

The chamber was pumped down to high vacuum (less than 10⁻² Pa) and heated to about 450-550° C. by heaters located inside the chamber. The blanks were then etched for 60 minutes in an Ar plasma.

At first, an innermost layer of Ti_{0.40}Al_{0.60}N (based on target composition) was deposited by only using the Ti_{0.40}Al_{0.60} target.

The chamber pressure (reaction pressure) was set to 4 Pa of N₂ gas, and a DC bias voltage of −50 V (relative to the chamber walls) was applied to the blank assembly. The cathodes were run in an arc discharge mode at a current of 150 A (each) for 70 minutes (2 flanges). The table rotational speed was 5 rpm. A layer of Ti_{0.40}Al_{0.60}N having a thickness of about 0.25 μm was deposited on the blanks.

Then, the nano-multilayer was deposited by using all mounted targets.

The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) for 35 minutes (4 flanges). The table rotational speed was 5 rpm. A nano-multilayer coating having a thickness of about 2.8 μm was deposited on the blanks.

The rotational speed correlates to a certain period thickness and it was concluded that a table rotational speed of 5 rpm for the current deposition rate and equipment used correlates to an average individual nanolayer thickness of each of the nanolayers Ti_{0.40}Al_{0.60}N, Cr_{0.30}Al_{0.70}N and Ti_{0.80}Si_{0.20}N of about 2 nm. The number of nanolayers in the nano-multilayer is about 1400.

The nano-multilayer comprises a repeating sequence of consecutive nanolayers in the order Ti_{0.40}Al_{0.60}N/Ti_{0.80}Si_{0.20}N/Cr_{0.30}Al_{0.70}N/Ti_{0.80}Si_{0.20}N.

In the nano-multilayer, the ratio of the sum of nanolayer thicknesses of each of the nanolayers Ti_{0.40}Al_{0.60}N, Cr_{0.30}Al_{0.70}N and Ti_{0.80}Si_{0.20}N, respectively, i.e., Ti_{0.40}Al_{0.60}N:Cr_{0.30}Al_{0.70}N:Ti_{0.80}Si_{0.20}N, is about 1:1:2. The ratio is estimated from a deposition rate from each target assumed to be the same, the rotation during deposition and the deposition time.

The actual elemental relation in a (Ti,Al)N layer of the nano-multilayer deposited using Ti_{0.40}Al_{0.60} targets was estimated to be Ti_{0.42}Al_{0.58}N.

The actual elemental relation in a (Cr,Al)N layer of the nano-multilayer deposited using Cr_{0.30}Al_{0.70} targets was estimated to be Cr_{0.32}Al_{0.68}N.

From EDS in TEM of a (Ti, Si)N single layer deposited under the same conditions as the (Ti, Si)N layers within the nano-multilayer the actual elemental relation in a (Ti, Si)N layer of the nano-multilayer deposited using Ti_{0.80}Si_{0.20} targets was estimated to be Ti_{0.83}Si_{0.17}N.

The coated cutting tools were called “Sample 1 (invention)”.

### Example 2

Coated cutting tools were provided comprising a nano-multilayer of Ti_{0.50}Al_{0.50}N, Cr_{0.30}Al_{0.70}N and Ti_{0.85}Si_{0.15}N (based on target compositions) nanolayers deposited on sintered cemented carbide cutting tool insert blanks of the geometries CNMG120408MM and R390-11T308M-PM. The composition of the cemented carbide was 10 wt % Co, 0.4 wt % Cr and rest WC. The cemented carbide blanks were coated by cathodic arc evaporation in a vacuum chamber comprising four arc flanges, each flange comprising several cathode evaporators. Targets of Ti_{0.50}Al_{0.50} were mounted in the evaporators in two of the flanges opposite each other. The remaining targets Cr_{0.30}Al_{0.70} and Ti_{0.85}Si_{0.15} were mounted in the evaporators in the two remaining flanges opposite each other. The targets were circular and planar with a diameter of 100 mm available on the open market. Suitable target technology packages for arc evaporation are available from suppliers on the market such as IHI Hauzer Techno Coating B.V., Kobelco (Kobe Steel Ltd.) and Oerlikon Balzers.

The uncoated blanks were mounted on pins that undergo a three-fold rotation in the PVD chamber.

The chamber was pumped down to high vacuum (less than 10⁻² Pa) and heated to about 450-550° C. by heaters located inside the chamber. The blanks were then etched for 60 minutes in an Ar plasma.

At first, an innermost layer of Ti_{0.50}Al_{0.50}N (based on target composition) was deposited by only using the Ti_{0.50}Al_{0.50} targets.

The chamber pressure (reaction pressure) was set to 4 Pa of N₂ gas, and a DC bias voltage of −50 V (relative to the chamber walls) was applied to the blank assembly. The cathodes were run in an arc discharge mode at a current of 150 A (each) for 70 minutes (2 flanges). The table rotational speed was 5 rpm. A layer of Ti_{0.50}Al_{0.50}N having a thickness of about 1.4 μm was deposited on the blanks.

Then, the nano-multilayer was deposited by alternating the use of the Cr_{0.30}Al_{0.70} and Ti_{0.85}Si_{0.15} targets, creating a first sequence of a Cr_{0.30}Al_{0.70}N/Ti_{0.85}Si_{0.15}N nano-multilayer of about 35 nm thickness. The table rotational speed was 5 rpm. Then only the Ti_{0.50}Al_{0.50} targets were used creating a Ti_{0.50}Al_{0.50}N layer of about 35 nm thickness. This procedure was repeated until 20 sequences of a nano-multilayer sequence of nanolayers Cr_{0.30}Al_{0.70}N and Ti_{0.85}Si_{0.15}N combined with a “monolayer” of Ti_{0.50}Al_{0.50}N was completed. The total thickness of the deposited nano-multilayer was about 1.4 μm.

The chamber pressure (reaction pressure) was set to 4 Pa of N₂ gas, and a DC bias voltage of −40 V (relative to the chamber walls) was applied to the blank assembly when using the Cr_{0.30}Al_{0.70} and Ti_{0.85}Si_{0.15} targets and a DC bias voltage of −80 V (relative to the chamber walls) when using the Ti_{0.50}Al_{0.50} targets. The cathodes were run in an arc discharge mode at a current of 150 A (each) for 70 minutes (2 flanges at a time). The table rotational speed was 5 rpm. A nano-multilayer coating having a thickness of about 1.4 μm was deposited on the blanks.

The rotational speed correlates to a certain period thickness and it was concluded that a table rotational speed of 5 rpm for the current deposition rate and equipment used correlates to an average individual nanolayer thickness of each of the nanolayers Cr_{0.30}Al_{0.70}N and Ti_{0.85}Si_{0.15}N of about 2 nm.

Finally, an outermost layer of Ti_{0.85}Si_{0.15}N (based on target composition), in order to obtain an even colour between the individual coated cutting tools made, was deposited by only using the Ti_{0.85}Si_{0.15} target. All deposition parameters were the same as for depositing the previous layers, except for the bias being-60 V and the cathodes were run for 10 minutes (1 flange). A layer of Ti_{0.85}Si_{0.15}N was deposited to a thickness of about 0.2 μm.

The actual elemental relation in a (Ti,Al)N layer deposited using Ti_{0.50}Al_{0.50} targets was estimated to be Ti_{0.52}Al_{0.48}N.

The actual elemental relation in a (Cr,Al)N layer deposited using Cr_{0.30}Al_{0.70} targets was estimated to be Cr_{0.32}Al_{0.68}N.

The actual elemental relation in a (Ti, Si)N layer deposited using Ti_{0.85}Si_{0.15} targets was estimated to be Ti_{0.87}Si_{0.13}N.

The coated cutting tools were called “Sample 2 (comparative)”.

### Example 3

Coated cutting tools were provided comprising a nano-multilayer of Ti_{0.50}Al_{0.50}N, Cr_{0.30}Al_{0.70}N and Ti_{0.80}Si_{0.20}N (based on target compositions) nanolayers deposited on sintered cemented carbide cutting tool insert blanks of the geometries CNMG120408MM and R390-11T308M-PM. The composition of the cemented carbide was 10 wt % Co, 0.4 wt % Cr and rest WC. The cemented carbide blanks were coated by cathodic arc evaporation in a vacuum chamber comprising four arc flanges, each flange comprising several cathode evaporators. Targets of Ti_{0.50}Al_{0.50} were mounted in the evaporators in two of the flanges opposite each other. The remaining targets Cr_{0.30}Al_{0.70} and Ti_{0.80} Si_{0.20} were mounted in the evaporators in the two remaining flanges opposite each other. The targets were circular and planar with a diameter of 100 mm available on the open market. Suitable target technology packages for arc evaporation are available from suppliers on the market such as IHI Hauzer Techno Coating B.V., Kobelco (Kobe Steel Ltd.) and Oerlikon Balzers.

The uncoated blanks were mounted on pins that undergo a three-fold rotation in the PVD chamber.

The chamber was pumped down to high vacuum (less than 10⁻² Pa) and heated to about 450-550° C. by heaters located inside the chamber. The blanks were then etched for 60 minutes in an Ar plasma.

At first, an innermost layer of Ti_{0.50}Al_{0.50}N (based on target composition) was deposited by only using the Ti_{0.50}Al_{0.50} targets.

The chamber pressure (reaction pressure) was set to 4 Pa of N₂ gas, and a DC bias voltage of −50 V (relative to the chamber walls) was applied to the blank assembly. The cathodes were run in an arc discharge mode at a current of 150 A (each) for 70 minutes (2 flanges). The table rotational speed was 5 rpm. A layer of Ti_{0.50}Al_{0.50}N having a thickness of about 1.4 μm was deposited on the blanks.

Then, the nano-multilayer was deposited by alternating the use of the Cr_{0.30}Al_{0.70} and Ti_{0.80}Si_{0.20} targets, creating a first sequence of a Cr_{0.30}Al_{0.70}N/Ti_{0.80}Si_{0.20}N nano-multilayer of about 35 nm thickness. The table rotational speed was 5 rpm. Then only the Ti_{0.50}Al_{0.50} targets were used creating a Ti_{0.50}Al_{0.50}N layer of about 35 nm thickness. This procedure was repeated until 20 sequences of a nano-multilayer sequence of nanolayers Cr_{0.30}Al_{0.70}N and Ti_{0.80}Si_{0.20}N combined with a “monolayer” of Ti_{0.50}Al_{0.50}N was completed. The total thickness of the deposited nano-multilayer was about 1.4 μm.

The chamber pressure (reaction pressure) was set to 4 Pa of N₂ gas, and a DC bias voltage of −40 V (relative to the chamber walls) was applied to the blank assembly when using the Cr_{0.30}Al_{0.70} and Ti_{0.80}Si_{0.20} targets and a DC bias voltage of −80 V (relative to the chamber walls) when using the Ti_{0.50}Al_{0.50} targets. The cathodes were run in an arc discharge mode at a current of 150 A (each) for 70 minutes (2 flanges at a time). The table rotational speed was 5 rpm. A nano-multilayer coating having a thickness of about 1.4 μm was deposited on the blanks.

The rotational speed correlates to a certain period thickness and it was concluded that a table rotational speed of 5 rpm for the current deposition rate and equipment used correlates to an average individual nanolayer thickness of each of the nanolayers Cr_{0.30}Al_{0.70}N and Ti_{0.80}Si_{0.20}N of about 2 nm.

Finally, an outermost layer of Ti_{0.80}Si_{0.20}N (based on target composition), in order to obtain an even colour between the individual coated cutting tools made, was deposited by only using the Ti_{0.80}Si_{0.20} target. All deposition parameters were the same as for depositing the previous layers, except for the bias being −60 V and the cathodes were run for 10 minutes (1 flange). A layer of Ti_{0.80}Si_{0.20}N was deposited to a thickness of about 0.2 μm.

The actual elemental relation in a (Ti,Al)N layer deposited using Ti_{0.50}Al_{0.50} targets was estimated to be Ti_{0.52}Al_{0.48}N.

The actual elemental relation in a (Cr,Al)N layer deposited using Cr_{0.30}Al_{0.70} targets was estimated to be Cr_{0.32}Al_{0.68}N.

The actual elemental relation in a (Ti, Si)N layer deposited using Ti_{0.80} Si_{0.20} targets was estimated to be Ti_{0.83}Si_{0.17}N.

The coated cutting tools were called “Sample 3 (comparative)”.

### Example 4

Coated cutting tools were provided comprising a nano-multilayer of Ti_{0.40}Al_{0.60}N, Cr_{0.30}Al_{0.70}N and Ti_{0.80}Si_{0.20}N (based on target compositions) nanolayers deposited on sintered cemented carbide cutting tool blanks being solid endmills, geometry 2P342-1200-PA, diameter 12 mm, with 4 cutting edges. The composition of the cemented carbide was 10 wt % Co, 0.4 wt % Cr and rest WC. The cemented carbide blanks were coated by cathodic arc evaporation in a vacuum chamber comprising four arc flanges, each flange comprising several cathode evaporators. Targets of Ti_{0.40}Al_{0.60} were mounted in the evaporators in two of the flanges opposite each other. The remaining targets Cr_{0.30}Al_{0.70} and Ti_{0.80}Si_{0.20} were mounted in the evaporators in the two remaining flanges opposite each other. The targets were circular and planar with a diameter of 100 mm available on the open market. Suitable target technology packages for arc evaporation are available from suppliers on the market such as IHI Hauzer Techno Coating B.V., Kobelco (Kobe Steel Ltd.) and Oerlikon Balzers.

The uncoated blanks were mounted on holders that undergo a three-fold rotation in the PVD chamber.

The chamber was pumped down to high vacuum (less than 10⁻² Pa) and heated to about 450-550° C. by heaters located inside the chamber. The blanks were then etched for 60 minutes in an Ar plasma.

At first, an innermost layer of Ti_{0.40}Al_{0.60}N (based on target composition) was deposited by only using the Ti_{0.40}Al_{0.60} targets.

The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) for 70 minutes (2 flanges). The table rotational speed was 5 rpm. A layer of Ti_{0.40}Al_{0.60}N having a thickness of about 1 μm was deposited on the blanks.

Then, the nano-multilayer was deposited by using all mounted targets.

The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) for 47 minutes (4 flanges). The table rotational speed was 5 rpm. A nano-multilayer coating having a thickness of about 2 μm was deposited on the blanks.

The rotational speed correlates to a certain period thickness and it was concluded that a table rotational speed of 5 rpm for the current deposition rate and equipment used correlates to an average individual nanolayer thickness of each of the nanolayers Ti_{0.40}Al_{0.60}N, Cr_{0.30}Al_{0.70}N and Ti_{0.80}Si_{0.20}N of about 2 nm. The number of nanolayers in the nano-multilayer is about 1000.

The nano-multilayer comprises a repeating sequence of consecutive nanolayers in the order Ti_{0.40}Al_{0.60}N/Cr_{0.30}Al_{0.70}N/Ti_{0.40}Al_{0.60}N/Ti_{0.80}Si_{0.20}N.

In the nano-multilayer, the ratio of the sum of nanolayer thicknesses of each of the nanolayers Ti_{0.40}Al_{0.50}N, Cr_{0.30}Al_{0.70}N and Ti_{0.80}Si_{0.20}N, respectively, i.e., Ti_{0.40}Al_{0.60}N:Cr_{0.30}Al_{0.70}N:Ti_{0.80}Si_{0.20}N, is about 2:1:1. The ratio is estimated from a deposition rate from each target assumed to be the same, the rotation during deposition and the deposition time.

The actual elemental relation in a (Ti,Al)N layer of the nano-multilayer deposited using Ti_{0.40}Al_{0.60} targets was estimated to be Ti_{0.42}Al_{0.58}N.

The actual elemental relation in a (Cr,Al)N layer of the nano-multilayer deposited using Cr_{0.30}Al_{0.70} targets was estimated to be Cr_{0.32}Al_{0.68}N.

From EDS in TEM of a (Ti, Si)N single layer deposited under the same conditions as the (Ti, Si)N layers within the nano-multilayer the actual elemental relation in a (Ti,Si)N layer of the nano-multilayer deposited using Ti_{0.80}Si_{0.20} targets was estimated to be Ti_{0.83}Si_{0.17}N.

The coated cutting tools were called “Sample 4 (invention)”.

The samples 1-4 made are listed in Table 1.

TABLE 1

| | | Nano-multilayer | | | |
|---|---|---|---|---|---|
| | | First | Second | Third | |
| | Inner | nanolayer | nanolayer | nanolayer | Outer |
| Sample | layer* | type* | type* | type* | layer* |
| 1 | Ti_{0.40}Al_{0.60}N, | Ti_{0.40}Al_{0.60}N | Cr_{0.30}Al_{0.70}N | Ti_{0.80}Si_{0.20}N | — |
| invention | 0.25 μm | 2.8 μm | | | |
| 2 | Ti_{0.50}Al_{0.50}N, | Ti_{0.50}Al_{0.50}N** | Cr_{0.30}Al_{0.70}N *** | Ti_{0.85}Si_{0.15}N *** | Ti_{0.85}Si_{0.15}N |
| comparative | 1.4 μm | 1.4 μm | | | 0.2 μm |
| 3 | Ti_{0.50}Al_{0.50}N, | Ti_{0.50}Al_{0.50}N** | Cr_{0.30}Al_{0.70}N *** | Ti_{0.80}Si_{0.20}N *** | Ti_{0.80}Si_{0.20}N |
| comparative | 1.4 μm | 1.4 μm | | | 0.2 μm |
| 4 | Ti_{0.40}Al_{0.60}N, | Ti_{0.40}Al_{0.60}N | Cr_{0.30}Al_{0.70}N | Ti_{0.80}Si_{0.20}N | — |

| | | |
|---|---|---|
| invention | 1 μm | 2 μm |

*all elemental compositions based on target composition
**about 35 nm TiAlN
*** about 35 nm nano-multilayer of CrAlN/TiSiN

Table 2 further summarises the samples 1-4.

TABLE 2

| | | | Thickness ratio |
|---|---|---|---|
| | | | sum of nanolayer |
| | | | thicknesses of |
| | Inner | Nanolayer sequence in | each nanolayer type |
| Sample | layer* | nano-multilayer* | Ti₁₋ₓAlₓN:Cr_{1-y}Al_{y}N:Ti_{1-z}Si_{z}N |
| 1 | Ti_{0.40}Al_{0.60}N, | (Ti_{0.40}Al_{0.60}N/Ti_{0.80}Si_{0.20}N/ | 1:1:2 |
| invention | 0.25 μm | Cr_{0.30}Al_{0.70}N/Ti_{0.80}Si_{0.20}N)₃₅₀ | |
| 2 | Ti_{0.50}Al_{0.50}N, | (35 nm Ti_{0.50}Al_{0.50}N + 35 nm | 2:1:1 |
| comparative | 1.4 μm | (Cr_{0.30}Al_{0.70}N/Ti_{0.85}Si_{0.15}N)₉)₂₀ | |
| 3 | Ti_{0.50}Al_{0.50}N, | (35 nm Ti_{0.50}Al_{0.50}N + 35 nm | 2:1:1 |
| comparative | 1.4 μm | (Cr_{0.30}Al_{0.70}N/Ti_{0.80}Si_{0.20}N)₉)₂₀ | |
| 4 | Ti_{0.40}Al_{0.60}N, | (Ti_{0.40}Al_{0.60}N/Cr_{0.30}Al_{0.70}N/ | 2:1:1 |
| invention | 1 μm | Ti_{0.40}Al_{0.60}N/Ti_{0.80}Si_{0.20}N)₂₅₀ | |

*all elemental compositions based on target composition

### Example 5

Cutting tests were made in order to determine the performance of the cutting tool insert samples made.

Since sample 1 was run at a separate test run as samples 2-3 the results are presented as compared with a cutting insert having an about 3 μm thick Ti_{0.40}Al_{0.60}N reference coating which was included in all test runs. For example, “155%” in the results table means the performance (tool life) was 155% of the result for the reference having a Ti_{0.40}Al_{0.60}N coating (based on target composition). The reference coated cutting tools were made by depositing a layer of Ti_{0.40}Al_{0.60}N on sintered cemented carbide cutting tool blanks of the same type as for samples 1-3, i.e., cutting tool insert blanks of the geometries CNMG120408MM and R390-11T308M-PM. The cemented carbide also being the same, i.e., 10 wt % Co, 0.4 wt % Cr and rest WC. Targets of Ti_{0.40}Al_{0.60} were mounted in the evaporators in four flanges. The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) (4 flanges). The table rotational speed was 5 rpm. A layer of Ti_{0.40}Al_{0.60}N having a thickness of about 3 μm was deposited on the blanks.

### Explanations to Terms Used

The following expressions/terms are commonly used in metal cutting, but nevertheless explained in the table below:
Vc (m/min): cutting speed in meters per minute
fz (mm/tooth): feed rate in millimeter per tooth (in milling)
fn (mm/rev) feed rate per revolution (in turning)
z: (number) number of teeth in the cutter
aₑ (mm): radial depth of cut in millimeter
aₚ (mm): axial depth of cut in millimeter

### Flank Wear Test:

### Longitudinal Turning

Work piece material: Sverker 21 (tool steel), Hardness ˜210HB, D=180, L=700 mm,
V_{c}=125 m/min
fₙ=0.072 mm/rev
aₚ=2 mm
   without cutting fluid

The cut-off criteria for tool life is a flank wear VB of 0.15 mm.

### Comb Crack Resistance:

Operation: Shoulder milling
Tool holder: C5-391.20-25 080
Work piece material: Toolox 33 (tool steel), L=600 mm, I=200 mm, h=100 mm,
Insert type: R390-11T308M-PM
Cutting speed V_{c}=250 m/min
Feed rate f_{z}=0.2 mm/rev
Depth of cut aₚ=3 mm
Radial engagement aₑ=12.5 mm
   with cutting fluid

The criteria for end of tool life is a max. chipped height VB>0.3 mm.

The results are presented in Table 3.

TABLE 3

| | Flank wear | Comb crack |
|---|---|---|
| | resistance | resistance |
| | (Tool life, % of | (Tool life, % of |
| Sample | Ti_{0.40}Al_{0.60}N ref.) | Ti_{0.40}Al_{0.60}N ref.) |
| 1 | 155% | 148% |
| invention | | |
| 2 | 91% | 89% |
| comparative | | |
| 3 | 96% | 86% |
| comparative | | |

It is concluded that sample 1, within the invention, have high flank wear resistance and show much less flank wear than comparative samples 2-3 outside the invention. Furthermore, sample 1 shows much higher comb crack resistance than the comparative samples.

### Example 6

Cutting tests were made in order to determine the performance of the cutting tool of sample 4 being an endmill.

Furthermore, to be used as a reference, coated cutting tools were made by depositing a layer of Ti_{0.40}Al_{0.60}N (based on target composition) on sintered cemented carbide cutting tool blanks of the same type as above, i.e., solid endmills, geometry 2P342-1200-PA, diameter 12 mm, with 4 cutting edges. The cemented carbide also being the same, i.e., 10 wt % Co, 0.4 wt % Cr and rest WC. Targets of Ti_{0.40}Al_{0.60} were mounted in the evaporators in four flanges. The chamber pressure (reaction pressure) was set to 4 Pa of N₂ gas, and a DC bias voltage of −50 V (relative to the chamber walls) was applied to the blank assembly. The cathodes were run in an arc discharge mode at a current of 150 A (each) (4 flanges). The table rotational speed was 5 rpm. A layer of Ti_{0.40}Al_{0.60}N having a thickness of about 3 μm was deposited on the blanks.

The coated cutting tools were called “Sample 5 (reference)”.

### Flank Wear Test:

### Dry Shoulder Milling

Work piece material: C45 (P1 steel), Hardness 200 HB, Size: 600×220×50 mm
Work piece material: 42CrMo4 (P2 steel), Hardness 302-305 HB, Size: 600×200×50 mm
V_{c}=235 m/min
fz=0.055 (mm/tooth)
aₚ=5 mm
aₑ=1.2 mm
z=4 teeth
L=220 mm (C45, P1 steel), 200 mm (42CrMo4, P2 steel) without cutting fluid

The predetermined number of cutting passes is 400, or Vb3≥0.1 mm.

Tool wear (Vb3-localised flank wear) was measured on tool corners and depth of cut (DOC) of the cutting edge. The lower values, the better.

Results from the test cutting in 42CrMo4, P2 steel, is seen in Table 4.

TABLE 4

| | Flank wear resistance | Flank wear resistance |
|---|---|---|
| | on corners | on depth of cut |
| Sample | (Vb3, mm) | (Vb3, mm) |
| 4 | 0.045 | 0.058 |
| invention | | |
| 5 | 0.072 | 0.073 |
| reference | | |

Results from the test cutting in C45, P1 steel, is seen in Table 5.

TABLE 5

| | Flank wear resistance | Flank wear resistance |
|---|---|---|
| | on corners | on depth of cut |
| Sample | (Vb3, mm) | (Vb3, mm) |
| 4 | 0.053 | 0.042 |
| invention | | |
| 5 | 0.078 | 0.076 |
| reference | | |

It is concluded from cutting in both work piece materials that sample 4, within the invention shows much less flank wear than the reference sample. The low levels of Vb3 are considered to be a very good result.

### Example 7

In order to evaluate the effect of different nanolayer thicknesses in the nano-multilayer the following samples were made:

Coated cutting tools were provided comprising a nano-multilayer of Ti_{0.40}Al_{0.60}N, Cr_{0.30}Al_{0.70}N and Ti_{0.80}Si_{0.20}N (based on target compositions) nanolayers deposited on sintered cemented carbide cutting tool insert blanks of the geometries CNMG120408MM and R390-11T308M-PM. The composition of the cemented carbide was 10 wt % Co, 0.4 wt % Cr and rest WC. The cemented carbide blanks were coated by cathodic arc evaporation in a vacuum chamber comprising four arc flanges, each flange comprising several cathode evaporators. Targets of Ti_{0.40}Al_{0.60} were mounted in the evaporators in two of the flanges opposite each other. The remaining targets Cr_{0.30}Al_{0.70} and Ti_{0.80}Si_{0.20} were mounted in the evaporators in the two remaining flanges opposite each other. The targets were circular and planar with a diameter of 100 mm available on the open market. Suitable target technology packages for arc evaporation are available from suppliers on the market such as IHI Hauzer Techno Coating B.V., Kobelco (Kobe Steel Ltd.) and Oerlikon Balzers.

The uncoated blanks were mounted on holders that undergo a three-fold rotation in the PVD chamber.

The chamber was pumped down to high vacuum (less than 10⁻² Pa) and heated to about 450-550° C. by heaters located inside the chamber. The blanks were then etched for 60 minutes in an Ar plasma.

At first, an innermost layer of Ti_{0.40}Al_{0.60}N (based on target composition) was deposited by only using the Ti_{0.40}Al_{0.60} targets.

The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) for 40 minutes (2 flanges). The table rotational speed was 5 rpm. A layer of Ti_{0.40}Al_{0.60}N having a thickness of about 0.8 μm was deposited on the blanks.

Then, the nano-multilayer was deposited by using all mounted targets.

The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) for 55 minutes (4 flanges). The table rotational speed was 5 rpm for a first sample, “Sample 5 (invention)”.

In a further run a second set of coated cutting tools were made using using the same process conditions as for making Sample 5 (invention) above but using a table rotational speed of 2.4 rpm. The coated cutting tools made were called “Sample 6 (comparative)”.

In a further run a third set of coated cutting tools were made using using the same process conditions as for making Sample 5 (invention) above but using a table rotational speed of 1.5 rpm. The coated cutting tools made were called “Sample 7 (comparative)”.

In all cases, a nano-multilayer coating having a thickness of about 2.2 μm was deposited on the blanks.

The rotational speed correlates to a certain period thickness and it was concluded that a table rotational speed of 5 rpm for the current deposition rate and equipment used correlates to an average individual nanolayer thickness of each of the nanolayers Ti_{0.40}Al_{0.60}N, Cr_{0.30}Al_{0.70}N and Ti_{0.80}Si_{0.20}N of about 2 nm. The number of nanolayers in the nano-multilayer is about 1000.

A table rotational speed of 2.4 rpm for the current deposition rate and equipment used correlates to an average individual nanolayer thickness of each of the nanolayers Ti_{0.40}Al_{0.60}N, Cr_{0.30}Al_{0.70}N and Ti_{0.80}Si_{0.20}N of about 4 nm. The number of nanolayers in the nano-multilayer is about 500.

A table rotational speed of 1.5 rpm for the current deposition rate and equipment used correlates to an average individual nanolayer thickness of each of the nanolayers Ti_{0.40}Al_{0.60}N, Cr_{0.30}Al_{0.70}N and Ti_{0.80}Si_{0.20}N of about 6 nm. The number of nanolayers in the nano-multilayer is about 330.

The nano-multilayers of Samples 5 to 7 all comprise a repeating sequence of consecutive nanolayers in the order Ti_{0.40}Al_{0.60}N/Cr_{0.30}Al_{0.70}N/Ti_{0.40}Al_{0.60}N/Ti_{0.80}Si_{0.20}N.

In the nano-multilayers, the ratio of the sum of nanolayer thicknesses of each of the nanolayers Ti_{0.40}Al_{0.50}N, Cr_{0.30}Al_{0.70}N and Ti_{0.80}Si_{0.20}N, respectively, i.e., Ti_{0.40}Al_{0.60}N:Cr_{0.30}Al_{0.70}N:Ti_{0.80}Si_{0.20}N, is about 2:1:1. The ratio is estimated from a deposition rate from each target assumed to be the same, the rotation during deposition and the deposition time.

The actual elemental relation in a (Ti,Al)N layer of the nano-multilayer deposited using Ti_{0.40}Al_{0.60} targets was estimated to be Ti_{0.42}Al_{0.58}N.

The actual elemental relation in a (Cr,Al)N layer of the nano-multilayer deposited using Cr_{0.30}Al_{0.70} targets was estimated to be Cr_{0.32}Al_{0.68}N.

From EDS in TEM of a (Ti, Si)N single layer deposited under the same conditions as the (Ti, Si)N layers within the nano-multilayer the actual elemental relation in a (Ti, Si)N layer of the nano-multilayer deposited using Ti_{0.80}Si_{0.20} targets was estimated to be Ti_{0.83}Si_{0.17}N.

### Example 8

A sample without an inner layer of (Ti,Al)N was made.

Coated cutting tools were provided comprising a nano-multilayer of Ti_{0.40}Al_{0.60}N, Cr_{0.30}Al_{0.70}N and Ti_{0.80}Si_{0.20}N (based on target compositions) nanolayers deposited on sintered cemented carbide cutting tool insert blanks of the geometries CNMG120408MM and R390-11T308M-PM. The composition of the cemented carbide was 10 wt % Co, 0.4 wt % Cr and rest WC. The cemented carbide blanks were coated by cathodic arc evaporation in a vacuum chamber comprising four arc flanges, each flange comprising several cathode evaporators. Targets of Ti_{0.40}Al_{0.60} were mounted in the evaporators in two of the flanges opposite each other. The remaining targets Cr_{0.30}Al_{0.70} and Ti_{0.80}Si_{0.20} were mounted in the evaporators in the two remaining flanges opposite each other. The targets were circular and planar with a diameter of 100 mm available on the open market. Suitable target technology packages for arc evaporation are available from suppliers on the market such as IHI Hauzer Techno Coating B.V., Kobelco (Kobe Steel Ltd.) and Oerlikon Balzers.

The uncoated blanks were mounted on holders that undergo a three-fold rotation in the PVD chamber.

The chamber was pumped down to high vacuum (less than 10⁻² Pa) and heated to about 450-550° C. by heaters located inside the chamber. The blanks were then etched for 60 minutes in an Ar plasma.

A nano-multilayer was deposited by using all mounted targets.

The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) for 75 minutes (4 flanges). The table rotational speed was 5 rpm.

A nano-multilayer coating having a thickness of about 3 μm was deposited on the blanks.

The rotational speed correlates to a certain period thickness and it was concluded that a table rotational speed of 5 rpm for the current deposition rate and equipment used correlates to an average individual nanolayer thickness of each of the nanolayers Ti_{0.40}Al_{0.60}N, Cr_{0.30}Al_{0.70}N and Ti_{0.80}Si_{0.20}N of about 2 nm. The number of nanolayers in the nano-multilayer is about 1000.

The nano-multilayer comprises a repeating sequence of consecutive nanolayers in the order Ti_{0.40}Al_{0.60}N/Cr_{0.30}Al_{0.70}N/Ti_{0.40}Al_{0.60}N/Ti_{0.80}Si_{0.20}N.

In the nano-multilayer, the ratio of the sum of nanolayer thicknesses of each of the nanolayers Ti_{0.40}Al_{0.50}N, Cr_{0.30}Al_{0.70}N and Ti_{0.80}Si_{0.20}N, respectively, i.e., Ti_{0.40}Al_{0.60}N:Cr_{0.30}Al_{0.70}N:Ti_{0.80}Si_{0.20}N, is about 2:1:1. The ratio is estimated from a deposition rate from each target assumed to be the same, the rotation during deposition and the deposition time.

The actual elemental relation in a (Ti,Al)N layer of the nano-multilayer deposited using Ti_{0.40}Al_{0.60} targets was estimated to be Ti_{0.42}Al_{0.58}N.

The actual elemental relation in a (Cr,Al)N layer of the nano-multilayer deposited using Cr_{0.30}Al_{0.70} targets was estimated to be Cr_{0.32}Al_{0.68}N.

From EDS in TEM of a (Ti, Si)N single layer deposited under the same conditions as the (Ti, Si)N layers within the nano-multilayer the actual elemental relation in a (Ti, Si)N layer of the nano-multilayer deposited using Ti_{0.80}Si_{0.20} targets was estimated to be Ti_{0.83}Si_{0.17}N.

The coated cutting tools were called “Sample 8 (invention)”.

Table 6 summarises the samples 5-8.

TABLE 6

| | | | Average |
|---|---|---|---|
| | | | nanolayer |
| | | | thickness of each |
| | | | nanolayer type |
| | Inner | Nanolayer sequence in | Ti₁₋ₓAlₓN, Cr_{1-y}Al_{y}N |
| Sample | layer* | nano-multilayer* | and Ti_{1-z}Si_{z}N |
| 5 | Ti_{0.40}Al_{0.60}N, | (Ti_{0.40}Al_{0.60}N/Cr_{0.30}Al_{0.70}N/ | 2 nm |
| invention | 0.8 μm | Ti_{0.40}Al_{0.60}N/Ti_{0.80}Si_{0.20}N)₂₅₀ | |
| 6 | Ti_{0.40}Al_{0.60}N, | (Ti_{0.40}Al_{0.60}N/Cr_{0.30}Al_{0.70}N/ | 4 nm |
| comparative | 0.8 μm | Ti_{0.40}Al_{0.60}N/Ti_{0.80}Si_{0.20}N)₁₂₅ | |
| 7 | Ti_{0.40}Al_{0.60}N, | (Ti_{0.40}Al_{0.60}N/Cr_{0.30}Al_{0.70}N/ | 6 nm |
| comparative | 0.8 μm | Ti_{0.40}Al_{0.60}N/Ti_{0.80}Si_{0.20}N)₈₃ | |
| 8 | — | (Ti_{0.40}Al_{0.60}N/Cr_{0.30}Al_{0.70}N/ | 2 nm |
| invention | | Ti_{0.40}Al_{0.60}N/Ti_{0.80}Si_{0.20}N)₂₅₀ | |

*all elemental compositions based on target composition

### Example 9

Cutting tests were made in order to determine the performance of the cutting tool insert samples 5 to 8.

A cutting insert having an about 3 μm thick Ti_{0.40}Al_{0.60}N reference coating which was included in all test runs. The reference coated cutting tools were made by depositing a layer of Ti_{0.40}Al_{0.60}N on sintered cemented carbide cutting tool blanks of the same type as for samples 5-8 to be tested, i.e., cutting tool insert blanks of the geometries CNMG120408MM and R390-11T308M-PM. The cemented carbide also being the same, i.e., 10 wt % Co, 0.4 wt % Cr and rest WC. Targets of Ti_{0.40}Al_{0.60} were mounted in the evaporators in four flanges. The chamber pressure (reaction pressure) was set to 4 Pa of N₂ gas, and a DC bias voltage of −70 V (relative to the chamber walls) was applied to the blank assembly. The cathodes were run in an arc discharge mode at a current of 150 A (each) (4 flanges). The table rotational speed was 5 rpm. A layer of Ti_{0.40}Al_{0.60}N having a thickness of about 3 μm was deposited on the blanks.

### Flank Wear Test:

### Longitudinal Turning

Work piece material: Sverker 21 (tool steel), Hardness ˜210HB, D=180, L=700 mm,
V_{c}=125 m/min
fₙ=0.072 mm/rev
aₚ=2 mm
   without cutting fluid

The cut-off criteria for tool life is a flank wear VB of 0.15 mm.

### Comb Crack Resistance:

Operation: Shoulder milling
Tool holder: C5-391.20-25 080
Work piece material: Toolox 33 (tool steel), L=600 mm, I=200 mm, h=100 mm,
Insert type: R390-11T308M-PM
Cutting speed V_{c}=250 m/min
Feed rate f_{z}=0.2 mm/rev
Depth of cut aₚ=3 mm
Radial engagement aₑ=12.5 mm
   with cutting fluid

The criteria for end of tool life is a max. chipped height VB>0.3 mm.

The results are presented in Table 7.

TABLE 7

| | | Flank wear | | Comb crack |
|---|---|---|---|---|
| | | resistance | Comb crack | resistance |
| | Flank wear | (Tool life, | resistance | (Tool life, |
| | resistance | % of | (Tool life, | % of |
| | (Tool life, | Ti_{0.40}Al_{0.60}N | number of | Ti_{0.40}Al_{0.60}N |
| Sample | minutes) | ref.) | passes) | ref.) |
| 5 | 22 | 129% | 37 | 95% |
| invention | | | | |
| 6 | 19 | 119% | 40 | 103% |
| comparative | | | | |
| 7 | 17 | 106% | 46 | 118% |
| comparative | | | | |
| 8 | 25 | 156% | 44 | 113% |
| invention | | | | |
| Ti_{0.40}Al_{0.60}N | 16 | 100% | 39 | 100% |
| reference | | | | |

It is concluded that sample 5, within the invention, has high flank wear resistance and shows less flank wear than comparative samples 6-7 outside the invention which have larger nanolayer thicknesses (averages 4 nm and 6 nm, respectively). Sample 8, without any inner (Ti,Al)N layer did also perform very well in the flank wear test and also shows a good result in comb crack resistance test. All samples did well in the comb crack resistance test, also Sample 5 within the invention with 37 passes in the test, but the samples within the invention show a combination of outstanding flank wear resistance in combination with a high comb crack resistance.

1. A coated cutting tool comprising a substrate and a coating, wherein the coating includes a from about 0.5 to about 10 μm nano-multilayer of alternating nanolayers of a first nanolayer type being Ti₁₋ₓAlₓN, wherein 0.45≤x<0.67, a second nanolayer type being Cr_{1-y}Al_{y}N, wherein 0.60≤y≤0.80, and a third nanolayer type being Ti_{1-z}Si_{z}N, wherein 0.14≤z≤0.25, an average nanolayer thickness of each of the nanolayer types Ti₁₋ₓAlₓN, Cr_{1-y}Al_{y}N and Ti_{1-z}Si_{z}N in the nano-multilayer is being ≥1 nm, but <3 nm.

2. The coated cutting tool according to claim 1, wherein there is a ratio in the nano-multilayer between a sum of a thickness of all of each nanolayer types Ti₁₋ₓAlₓN:Ti_{1-y}Si_{y}N:Ti_{1-z}Al_{z}N, being a:b:c, and wherein 0.5<a<3, 0.5<b<3, 0.5<c<3.

3. The coated cutting tool according to claim 1, wherein for the first nanolayer type being Ti₁₋ₓAlₓN, suitably and wherein 0.50≤x≤0.62.

4. The coated cutting tool according to claim 1, wherein for the second nanolayer type being Cr_{1-y}Al_{y}N, and wherein 0.65≤y≤0.75.

5. The coated cutting tool according to claim 1, wherein for the third nanolayer type being Ti_{1-z}Si_{z}N, and wherein 0.15≤z≤0.23.

6. The coated cutting tool according to claim 1, wherein the average nanolayer thickness in the nano-multilayer, of each of the nanolayer types Ti₁₋ₓAlₓN, Ti_{1-y}Si_{y}N, and Ti_{1-z}Al_{z}N in the nano-multilayer, is from 1 to 2.5 nm.

7. The coated cutting tool according to claim 1, wherein a ratio of average nanolayer thickness in the nano-multilayer between any one of the nanolayer types Ti₁₋ₓAlₓN, Cr_{1-y}Al_{y}N and Ti_{1-z}Si_{z}N to any of the remaining two of the nanolayer types Ti₁₋ₓAlₓN, Cr_{1-y}Al_{y}N and Ti_{1-z}Si_{z}N in the nano-multilayer is of from 0.1 to 10.

8. The coated cutting tool according to claim 1, wherein within a sequence of 10 consecutive nanolayers in the nano-multilayer all of the nanolayer types Ti₁₋ₓAlₓN, Cr_{1-y}Al_{y}N and Ti_{1-z}Si_{z}N present are present.

9. The coated cutting tool according to claim 2, wherein there is a ratio in the nano-multilayer between the sum of nanolayer thicknesses of each nanolayer type, Ti₁₋ₓAlₓN:Cr_{1-y}Al_{y}N:Ti_{1-z}Si_{z}N, in the nano-multilayer, a:b:c, wherein 0.75<a<1.25, 0.75<b<1.25, 1.5<c<2.5.

10. The coated cutting tool according to claim 2, wherein there is a ratio in the nano-multilayer between the sum of nanolayer thicknesses of each nanolayer type, Ti₁₋ₓAlₓN:Cr_{1-y}Al_{y}N:Ti_{1-z}Si_{z}N, in the nano-multilayer, a:b:c, wherein 1.5<a<2.5, 0.75<b<1.25, 0.75<c<1.25.

11. The coated cutting tool according to claim 1, wherein the thickness of the nano-multilayer is from about 1 to about 8 μm.

12. The coated cutting tool according to claim 1, wherein the coating includes an inner layer of TiN or N below the nano-multilayer closest to the substrate, the inner layer having a thickness of from about 0.1 to about 3 μm.

13. The coated cutting tool according to claim 12, wherein the inner layer is Ti₁₋ₜAlₜN, and wherein 0.35≤t≤0.70.

14. The coated cutting tool according to claim 1, wherein the substrate of the coated cutting tool is selected from the group of cemented carbide, cermet, ceramic, cubic boron nitride and high speed steel.

15. The coated cutting tool according to claim 1, wherein the coated cutting tool is a cutting tool insert, a drill, or a solid end-mill, for metal machining.
